(19) United States
(12) Patent Application Publication
(10) Pub. No.: US 2026/0169336 A1
(43) Pub. Date: Jun. 18, 2026

(54) LIQUID CRYSTAL DISPLAY DEVICE

(71) Applicant: LG DISPLAY CO., LTD., SEOUL (KR)

(72) Inventors: Jinuk Lee, Seoul (KR); ChangEun Kim, Seoul (KR)

(21) Appl. No.: 19/374,114

(22) Filed: Oct. 30, 2025

(30) Foreign Application Priority Data
Dec. 18, 2024 (KR) 10-2024-0190425

(51) Int. Cl. G02F 1/1368; G02F 1/1362; H10D 30/67; H10D 86/60

(52) U.S. Cl. CPC G02F 1/1368; G02F 1/136209; G02F 1/136222; H10D 30/6732; H10D 30/6736; H10D 30/6737; H10D 86/60

(57) ABSTRACT

A liquid crystal display device includes an upper substrate including a black matrix and a color filter; a lower substrate disposed opposite to the upper substrate; a multi-buffer layer disposed on the lower substrate; a thin-film transistor including a gate electrode, an active layer, a source electrode, and a drain electrode, the thin-film transistor being disposed on the multi-buffer layer; and a liquid crystal layer disposed on the thin-film transistor. The gate electrode includes aluminum alloy.

### CROSS-REFERENCE TO RELATED APPLICATIONS

Pursuant to 35 U.S.C. § 119 (a), this application claims the benefit of an earlier filing date and right of priority to Korean Patent Application No. 10-2024-0190425 filed on Dec. 18, 2024, in the Korean Intellectual Property Office, the disclosure of which is incorporated herein by reference in its entirety.

### TECHNICAL FIELD

The present specification relates to liquid crystal display devices.

### BACKGROUND

Recently, a display field for visually expressing electrical information signals has been rapidly developed as the information age has come in earnest. Therefore, various display devices, which are thin and lightweight and have excellent performances such as low power consumption, have been developed. Specific examples of the display devices may include a liquid crystal display (LCD) device, a plasma display panel (PDP) device, a field emission display (FED) device, and an organic light-emitting display (OLED) device.

Among the display devices, the liquid crystal display device includes a liquid crystal panel made by injecting a liquid crystal material between two substrates disposed to be opposite to each other and having electrodes for generating electric fields, and a backlight unit positioned below the liquid crystal panel and configured to emit light. The liquid crystal display device may display images by adjusting the light emitted from the backlight unit by controlling optical anisotropy and double refraction properties of a liquid crystal molecule by using an electric field generated by applying voltages to the two electrodes of the liquid crystal panel.

### SUMMARY

A liquid crystal display device according to an implementation of the present specification includes: an upper substrate including a black matrix and a color filter; a lower substrate disposed opposite to the upper substrate; a multi-buffer layer disposed on the lower substrate; a thin-film transistor including a gate electrode, an active layer, a source electrode, and a drain electrode, the thin-film transistor being disposed on the multi-buffer layer; and a liquid crystal layer disposed on the thin-film transistor. The gate electrode includes aluminum alloy.

Other detailed matters of the example implementations are included in the detailed description and the drawings.

### BRIEF DESCRIPTION OF DRAWINGS

The above and other aspects, features and other advantages of the present disclosure will be more clearly understood from the following detailed description taken in conjunction with the accompanying drawings.

FIG. 1 is a schematic top plan view of a liquid crystal display device according to an implementation of the present specification.

FIG. 2 is a schematic cross-sectional view of the liquid crystal display device according to the implementation of the present specification.

FIG. 3A is a schematic cross-sectional view for explaining a liquid crystal display panel of the liquid crystal display device according to the implementation of the present specification.

FIG. 3B is an enlarged cross-sectional view of area A in FIG. 3A according to the implementation of the present specification.

FIG. 4 is a graph illustrating rear reflectance with respect to wavelengths in Example 1 and Comparative Examples 1 and 2.

FIGS. 5A to 5D are SEM images illustrating cross-sections of a gate electrode configured by two layers made of aluminum alloy and copper.

### DETAILED DESCRIPTION

Implementations of the present specification can provide a liquid crystal display device capable of improving luminance and reducing power consumption of a backlight unit.

Implementations of the present specification can also provide a liquid crystal display device capable of improving rear reflectance and luminous efficiency of a liquid crystal display panel.

Implementations of the present specification can also provide a liquid crystal display device capable of improving heat resistance of a thin-film transistor.

Objects of the present disclosure are not limited to the above-mentioned objects, and other objects, which are not mentioned above, can be clearly understood by those skilled in the art from the following descriptions.

Implementations of the present specification can provide various technical effects. For example, implementations can improve the rear reflectance of the liquid crystal display panel by means of the gate electrode with a dual-layer structure made of aluminum alloy and copper.

Implementations of the present specification can also improve the heat resistance and durability by adjusting the content of dopant materials in the aluminum alloy and form the gate electrode suitable for wet etching.

Implementations of the present specification can also significantly improve the rear reflectance of the liquid crystal display panel by disposing the multi-buffer layer below the aluminum alloy.

Implementations of the present specification can also improve the luminous efficiency of the backlight unit, reduce the power consumption, and improve the luminance of the liquid crystal display device by improving the rear reflectance of the liquid crystal display panel.

The effects according to the present disclosure are not limited to the contents exemplified above, and more various effects are included in the present specification.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with implementations of the disclosure.

It is to be understood that both the foregoing general description and the following detailed description are examples and explanatory and are intended to provide further explanation of the disclosure as claimed.

Reference will now be made in detail to implementations of the present disclosure, examples of which may be illustrated in the accompanying drawings. In the following description, when a detailed description of well-known functions or configurations related to this document is determined to unnecessarily cloud a gist of the disclosure, the detailed description thereof will be omitted or may be briefly discussed. The progression of processing steps and/or operations described is an example; however, the sequence of steps and/or operations is not limited to that set forth herein and may be changed as is known in the art, with the exception of steps and/or operations necessarily occurring in a particular order. Like reference numerals designate like elements throughout. Names of the respective elements used in the following explanations may be selected only for convenience of writing the specification and may be thus different from those used in actual products.

Advantages and characteristics of the present disclosure and a method of achieving the advantages and characteristics will be clear by referring to example implementations described below in detail together with the accompanying drawings. However, the present disclosure is not limited to the example implementations disclosed herein but will be implemented in various forms. The example implementations are provided by way of example only so that those skilled in the art can fully understand the disclosures of the present disclosure and the scope of the present disclosure.

The shapes, sizes, ratios, angles, numbers, and the like illustrated in the accompanying drawings for describing the example implementations of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Any implementation described herein as an “example” is not necessarily to be construed as preferred or advantageous over other implementations.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

Also, when an element or layer is “connected,” “coupled,” or “adhered” to another element or layer denotes that the element or layer can not only be directly connected or adhered to anotherthe other element or layer, but also be indirectly connected or adhered to anotherthe other element or layer with one or more intervening elements or layers “disposed,” or “interposed” between the elements or layers, unless otherwise specified. It should be understood to mean that elements may be so disposed to directly contact each other, or may be so disposed without directly contacting each other.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

Unless otherwise defined, all terms (including technical and scientific terms) used herein have the same meaning as commonly understood by one of ordinary skill in the art to which example implementations belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these implementations may be provided so that this disclosure may be sufficiently thorough and complete to assist those skilled in the art to fully understand the scope of the present disclosure. Furthermore, the present disclosure is only defined by scopes of claims.

The features of various implementations of the present disclosure can be partially or entirely adhered to or combined with each other and can be interlocked and operated in technically various ways, and the implementations can be carried out independently of or in association with each other.

Hereinafter, an example implementation of the present disclosure will be described in detail with reference to the drawings.

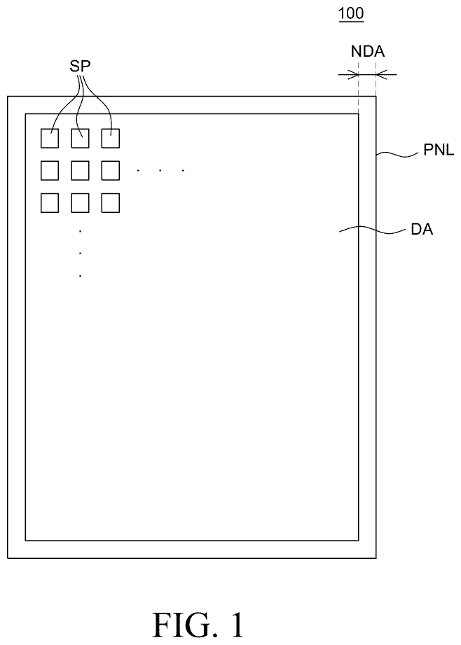

FIGS. 1 to 3B are views for explaining a liquid crystal display device according to an implementation of the present specification.

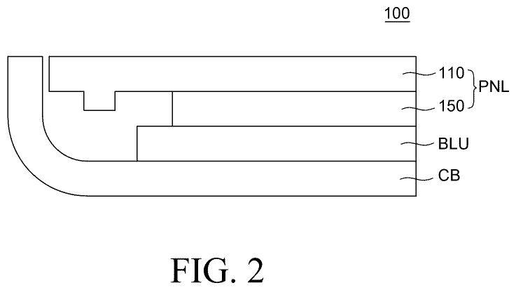

FIG. 1 is a schematic top plan view of the liquid crystal display device according to the implementation of the present specification. FIG. 2 is a schematic cross-sectional view of the display device according to the implementation of the present specification. For convenience of description, FIG. 1 illustrates only a liquid crystal display panel PNL and a plurality of subpixels SP among various components of a liquid crystal display device 100.

With reference to FIGS. 1 and 2, the liquid crystal display device 100 according to the present specification includes the liquid crystal display panel PNL, which includes a first substrate 110 and a second substrate 150, a backlight unit BLU, a cover bottom CB, and a cover window CW.

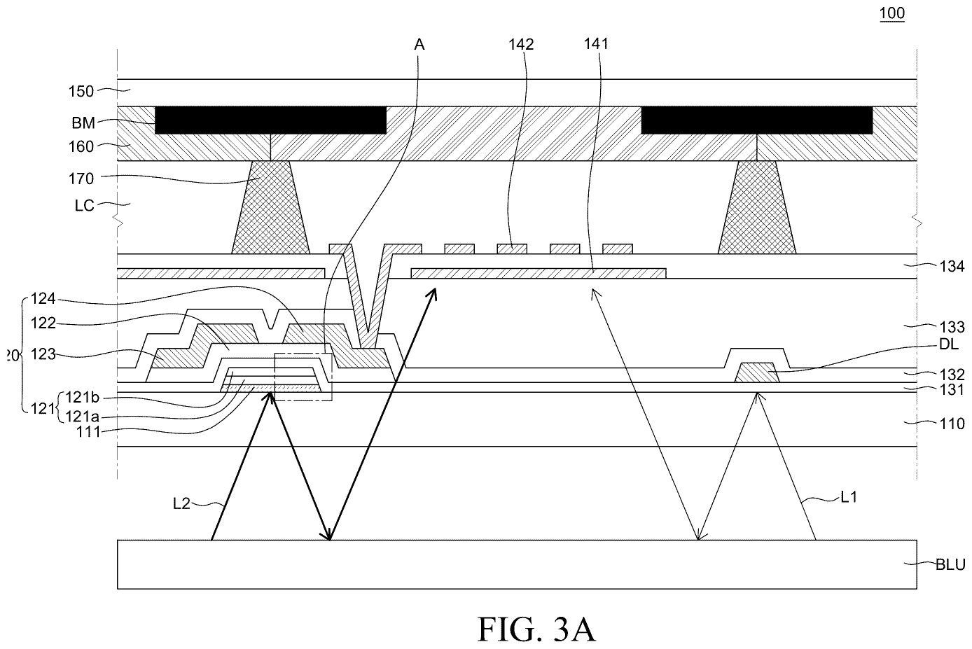

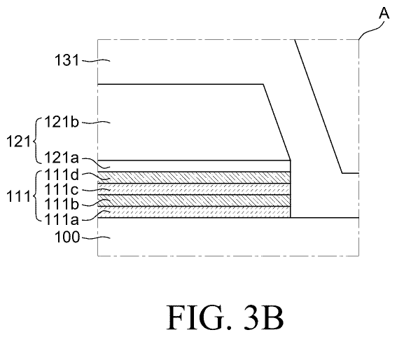

Pixels are arranged in a matrix shape on the liquid crystal display panel PNL, and the liquid crystal display panel PNL outputs images. In order to adjust the light transmittance, the liquid crystal display panel PNL includes the first substrate 110 and the second substrate 150 joined with a liquid crystal layer LC interposed therebetween. A specific structure of the liquid crystal display panel PNL will be described below with reference to FIG. 3.

The liquid crystal display panel PNL includes a display area DA and a non-display area NDA. The display area DA is an area in which the plurality of subpixels SP is disposed, and actual images are displayed. The non-display area NDA is an outer peripheral area configured to surround the display area DA, and no image is displayed in the non-display area NDA. The non-display area NDA will be referred to as a bezel area. A line and a drive circuit are disposed in the non-display area NDA to operate a screen.

The plurality of subpixels SP may be defined on the liquid crystal display panel PNL. The plurality of subpixels SP is minimum units that constitute the display area DA. The plurality of subpixels SP may each have an area for displaying one color. For example, the plurality of subpixels SP may include red subpixels, green subpixels, and blue subpixels. As illustrated in FIG. 1, the plurality of subpixels SP may be defined in a matrix shape.

The pixels are arranged in a matrix shape on the liquid crystal display panel PNL, and the liquid crystal display panel PNL outputs images. In order to adjust the light transmittance, the liquid crystal display panel PNL includes the first substrate 110 and the second substrate 150 joined with the liquid crystal layer LC interposed therebetween. A specific structure of the liquid crystal display panel PNL will be described below with reference to FIG. 3.

The backlight unit BLU is disposed below the liquid crystal display panel PNL and supplies light to the liquid crystal display panel PNL. The backlight unit BLU may include a light source, a reflective film, a light guide plate, a guide panel, an optical film, and the like. In this case, the backlight unit BLU may use any one of a cold cathode fluorescence lamp (CCFL), a hot cathode fluorescence lamp (HCFL), an external electrode fluorescence lamp (EEFL), or a light emitting diode (LED) selected as a light source. However, the present specification is not limited thereto.

The cover bottom CB is a casing member configured to accommodate and protect the constituent elements of the liquid crystal display device 100. The cover bottom CB may surround a side surface of the liquid crystal display panel PNL and a side surface of the backlight unit BLU and be disposed on a rear surface of the backlight unit BLU. Specifically, the cover bottom CB may be formed in the form of a quadrangular frame having an edge bent vertically. For example, the cover bottom CB may include a horizontal portion disposed opposite to the rear surface of the backlight unit BLU, and a vertical portion extending from the horizontal portion and disposed to surround the side surface of the liquid crystal display panel PNL and the side surface of the backlight unit BLU.

The cover bottom CB may include a material with high thermal conductivity and high rigidity in order to smoothly discharge heat to the outside from the drive circuit and the light source of the backlight unit BLU. For example, the cover bottom CB may be manufactured as a metal plate such as aluminum, aluminum nitride (AlN), electro-galvanized steel sheet (EGI), stainless (SUS), galvalume (SGLC), aluminum-coated steel sheet (commonly known as ALCOSTA), or tin-coated steel sheet (SPTE). However, the present specification is not limited thereto.

The cover window CW protects the liquid crystal display panel PNL from external impact and scratches. Therefore, the cover window CW may be made of a transparent material excellent in impact resistance and scratch resistance. In addition, the cover window CW protects the liquid crystal display panel PNL from moisture or the like permeating from the outside. Therefore, the cover window CW may suppress a deterioration in display quality caused by degradation of the liquid crystal display panel PNL.

The cover window CW may be implemented as a plastic-based cover in order to implement the liquid crystal display device 100 that is thin and lightweight. For example, the cover window CW may be a film made of polymer such as polyimide, polyamide-imide, polyethylene terephthalate, polymethyl methacrylate, polypropylene glycol, or polycarbonate. Alternatively, the cover window CW may be a film made of optically isotropic polymer such as cycloolefin (co) polymer, optically isotropic polycarbonate, or optically isotropic polymethyl methacrylate. In addition, the cover window CW may have a multilayer structure in which various functional layers are stacked. For example, the cover window CW may include various functional layers such as an external light reflection reduction layer, a UV blocking layer, and a hard coating layer.

Meanwhile, although not illustrated in FIG. 2, a polarizing plate may be disposed on at least one of the front surface and the rear surface of the liquid crystal display panel PNL. For example, the polarizing plate may be disposed on a bottom surface of the first substrate 110 or disposed on a top surface of the second substrate 150. However, the present specification is not limited thereto.

Hereinafter, the liquid crystal display panel PNL of the liquid crystal display device 100 according to the implementation of the present specification will be described with reference to FIG. 3. FIG. 3A is a schematic cross-sectional view for explaining the liquid crystal display panel of the liquid crystal display device according to the implementation of the present specification. FIG. 3B is an enlarged cross-sectional view of area A in FIG. 3A.

The liquid crystal display panel PNL may operate in a fringe-field switching (FFS) manner that implements images as a fringe field, which is formed between a common electrode 141, which is a common electrode, and a pixel electrode 142, which is a pixel electrode, penetrates a slit and operates liquid crystal molecules of the liquid crystal layer LC positioned in the pixel area. In another example, the liquid crystal display panel PNL may operate in an in-plane switching (IPS) manner that implements images as the common electrode 141, which is the common electrode, and the pixel electrode 142, which is the pixel electrode, are disposed in parallel and operate liquid crystal molecules of the liquid crystal layer LC by horizontal electric fields of the common electrode 141 and the pixel electrode 142.

With reference to FIG. 3, the liquid crystal display panel PNL includes the first substrate 110 and the second substrate 150.

The first substrate 110 may be a lower substrate configured to support various constituent elements included in the liquid crystal display device 100 and protect various constituent elements included in the liquid crystal display device 100 from external impact or external environments. The first substrate 110 may be made of an insulating material. For example, the first substrate 110 may be configured as a glass substrate or a plastic substrate may be made of polyethylene terephthalate (PET), polyethylene naphthalate (PEN), polyimide, or the like.

The first substrate 110 supports various constituent elements of the liquid crystal display panel PNL. As in the above-mentioned liquid crystal display panel PNL, the first substrate 110 may include the display area DA and the non-display area NDA. A thin-film transistor 120 and various types of lines and electrodes may be formed on the first substrate 110 and define the plurality of subpixels. The second substrate 150 may have a color filter 160 configured to display three primary colors, i.e., red, green, and blue colors, and a black matrix BM configured to separate the subpixels.

A plurality of gate lines and a plurality of data lines are disposed on the first substrate 110 while intersecting one another. The thin-film transistor 120 may be disposed in the area in which the gate lines and the data lines intersect. The thin-film transistor 120 may be connected to the pixel electrode 142 disposed in the display area DA.

The thin-film transistor 120 is disposed on the first substrate 110. The thin-film transistor 120 includes a gate electrode 121, an active layer 122, a source electrode 123, and a drain electrode 124. In the liquid crystal display device 100 according to the implementation of the present specification, the thin-film transistor 120 is the thin-film transistor 120 having a bottom gate structure in which the active layer 122 is disposed on the gate electrode 121, the source electrode 123 and the drain electrode 124 are disposed on the active layer 122, and the gate electrode 121 is disposed at a lowermost side.

The gate electrode 121 of the thin-film transistor 120 extends from the gate line. The gate electrode 121 may reflect the light, which is emitted from the backlight unit BLU disposed below the first substrate 110, to a rear side.

The gate electrode 121 may include a plurality of layers. For example, the gate electrode 121 may include two layers. Specifically, the gate electrode 121 may include a first gate metal layer 121a and a second gate metal layer 121b. The first gate metal layer 121a and the second gate metal layer 121b may be sequentially stacked on the first substrate 110.

The first gate metal layer 121a is disposed on the first substrate 110. The first gate metal layer 121a reflects the light emitted from the backlight unit BLU disposed therebelow.

The first gate metal layer 121a may be made of aluminum alloy. The aluminum alloy has high reflectance and excellent wet etching characteristics and suppresses atomic diffusion to the second gate metal layer 121b positioned above the first gate metal layer 121a.

The aluminum alloy includes aluminum and dopant materials. The dopant material may be one or more materials selected from a group including neodymium (Nd), germanium (Ge), zirconium (Zr), tantalum (Ta), cerium (Ce), niobium (Nb), molybdenum (Mo), tungsten (W), rhenium (Re), titanium (Ti), vanadium (V), chromium (Cr), hafnium (Hf), ruthenium (Ru), osmium (Os), scandium (Sc), and iridium (Ir). For example, the aluminum alloy may include one or more of aluminum, neodymium (Nd), germanium (Ge), zirconium (Zr), and tantalum (Ta). However, the present specification is not limited thereto. In general, in case that aluminum is used for the electrode, the aluminum is subjected to a high-temperature process at 400° C. or more or exposed to a high-temperature environment in order to form another layer, and fine protruding portions are formed on the surface of the aluminum electrode, which causes a hillock. However, in case that the above-mentioned dopant materials are included in aluminum, aluminum alloys such as Al₃Nd, Al₃Nb, and Al₃Ce precipitate in the form of particles at the aluminum grain boundaries in a high-temperature environment, which may further improve durability. Therefore, the occurrence of a hillock at a high temperature may be suppressed, and the heat resistance of the gate electrode may be improved.

The total content of the dopant material may be from 1.0 wt % to 5.0 wt % or from 2.0 wt % to 4.0 wt % based on the entire aluminum alloy. In case that the total content of the dopant material satisfies the above-mentioned range, excellent heat resistance and wet etching characteristics may be achieved. The total content of the dopant material refers to the content of all dopant materials in the entire aluminum alloy in case that the plurality of dopant materials is included in the aluminum alloy.

For example, the aluminum alloy may include one or more of neodymium, germanium, zirconium, and tantalum. In this case, in the entire aluminum alloy, the content of aluminum may be from 86 wt % to 99 wt %, the content of neodymium may be from 0.1 wt % to 5 wt %, the content of germanium may be from 0.1 wt % to 3 wt %, the content of tantalum may be from 0.1 wt % to 3 wt %, and the content of zirconium may be from 0 wt % to 3 wt %.

Aluminum is a material having surface resistance of about 0.15 Ω/□ (0.15 ohms per square) relatively lower than surface resistance of molybdenum (Mo) that is about 0.55 Ω/□(0.55 ohms per square). Therefore, the first gate metal layer 121a including aluminum alloy may have sufficient conductivity even though the first gate metal layer 121a is formed to have a small thickness. In addition, because the aluminum alloy has relatively higher reflectance than molybdenum (Mo) or the like, the aluminum alloy may reflect the light emitted from the backlight unit BLU, which is disposed therebelow, downward again.

A thickness of the first gate metal layer 121a may be from 100 Å to 1000 Å or from 300 Å to 800 Å. The rear reflectance of the liquid crystal display panel PNL may be improved in case that the thickness of the first gate metal layer 121a satisfies the above-mentioned range.

The second gate metal layer 121b is disposed on the first gate metal layer 121a. The second gate metal layer 121b may serve as resistance of the gate electrode 121. The second gate metal layer 121b may be made of a metallic material having low resistance. For example, the second gate metal layer 121b may be made of copper (Cu) or copper alloy. Because the second gate metal layer 121b is made of copper or copper alloy, the second gate metal layer 121b may have low resistance and be used for a wet etching process. The second gate metal layer 121b may have a height of from 2000 Å to 6000 Å. However, the present specification is not limited thereto.

Meanwhile, the gate electrode 121 may be formed by deposition and photolithography processes. For example, aluminum alloy may be deposited, and then copper may be continuously deposited in the same chamber. Alternatively, aluminum alloy may be deposited and exposed to the atmosphere, and then copper is deposited in another chamber. Thereafter, photoresist is applied over the entire area, and exposure and wet etching processes using a mask are performed, such that the gate electrode 121, which includes the first gate metal layer 121a made of aluminum alloy and the second gate metal layer 121b made of copper, is formed. In this case, a degree to which aluminum alloy is etched during the etching process varies depending on the content of the dopant material in the aluminum alloy that constitutes the first gate metal layer 121a. As described above, the content of the dopant material may be from 1.0 wt % to 5.0 wt % or from 2.0 wt % to 4.0 wt % based on the entire aluminum alloy. In case that the content of the dopant material is smaller than the range, an etching rate for aluminum alloy may increase, which may cause an undercut in which a part of the bottom surface of the first gate metal layer 121a is exposed. In addition, in case that the content of the dopant material is larger than the range, the etching rate for aluminum alloy may decrease, and the etching process may not be performed. Therefore, the display device 100 according to the implementation of the present specification may ensure a profile for a wet etching process by adjusting a content ratio or atom ratio of the aluminum alloy that constitutes the first gate metal layer 121a.

A multi-buffer layer 111 is disposed between the first substrate 110 and the gate electrode 121. During the process of forming the thin-film transistor 120, the multi-buffer layer 111 blocks impurities introduced from the first substrate 110, suppresses the permeation of moisture and hydrogen from the outside, and protects various constituent elements of the display device 100. In addition, the multi-buffer layer 111 improves the rear reflectance of the gate electrode 121.

The multi-buffer layer 111 may include a plurality of layers, e.g., two layers, four layers, or six layers. For example, the multi-buffer layer 111 includes at least one first buffer layer 111a or 111c and at least one second buffer layer 111b or 111d. Specifically, with reference to FIGS. 3A and 3B, the multi-buffer layer 111 may include four layers formed by stacking the first buffer layers 111a and 111c and the second buffer layers 111b and 111d in alternation with each other in a sequence from the first substrate 110.

The first buffer layers 111a and 111c and the second buffer layers 111b and 111d may each be made of an insulating material, e.g., silicon nitride (SiNx), silicon oxide (SiOx), or silicon oxynitride (SiON).

In this case, a refractive index of each of the first buffer layers 111a and 111c may be higher than a refractive index of each of the second buffer layers 111b and 111d. For example, the refractive index of each of the first buffer layers 111a and 111c may be from 1.8 to 2.2 or from 1.9 to 2.1, and the refractive index of each of the second buffer layers 111b and 111d may be from 1.3 to 1.7 or from 1.4 to 1.6. Particularly, the refractive index of each of the first buffer layers 111a and 111c may be 1.98, and the refractive index of each of the first buffer layers 111a and 111c may be 1.50. However, the present specification is not limited thereto. In order to match the above-mentioned refractive index, the first buffer layers 111a and 111c may be made of silicon nitride (SiNx), and the second buffer layers 111b and 111d may be made of silicon oxide (SiO₂). However, the present specification is not limited thereto.

Because the multi-buffer layer 111 has the structure in which the first buffer layers 111a and 111c and the second buffer layers 111b and 111d having different refractive indices are disposed in alternation with each other, a resonance effect occurs because of the difference in refractive index between the first buffer layers 111a and 111c and the second buffer layers 111b and 111d, thereby improving light extraction efficiency. Therefore, when the light, which is emitted from the backlight unit BLU and passes through the multi-buffer layer 111, is reflected by the rear surface of the gate electrode 121, the reflectance implemented by the gate electrode 121 may be improved.

Therefore, light recycling efficiency of the backlight unit BLU may be improved, and power consumption of the backlight unit BLU may be reduced. Specifically, with reference to FIG. 3A, first light L1, which is emitted from the backlight unit BLU, is introduced into the first substrate 110 of the liquid crystal display panel PNL and reflected by the rear surface of the gate electrode 121. The reflected light is reflected by the backlight unit BLU again and passes through the color filter 160 through an opening area of the subpixel. In addition, second light L2 emitted from the backlight unit BLU is introduced into the first substrate 110 of the liquid crystal display panel PNL and reflected by a rear surface of a data line DL. Like the first light L1, the reflected light is reflected by the backlight unit BLU again and passes through the color filter 160 through the opening area of the subpixel. In this case, the first light L1 reflected by the gate electrode 121 is larger in light amount than the second light L2 reflected by the data line DL. That is, the reflectance of the gate electrode 121 is higher than the reflectance of the data line DL. With the gate electrode 121, which includes two layers made of aluminum alloy and copper as described above, and the multi-buffer layer 111 disposed below the gate electrode, it is possible to improve the rear reflectance of the liquid crystal display panel PNL and reduce the efficiency and power consumption of the backlight unit BLU.

The thicknesses of the first buffer layers 111a, 111c, and second buffer layers 111b, 111d may vary depending on the number of times the first buffer layers 111a, 111c, and second buffer layers 111b, 111d are stacked. The multi-buffer layer 111 may be configured to improve the rear reflectance implemented by the gate electrode 121, and the rear reflectance may be adjusted depending on the number of first buffer layers 111a and 111c having high refractive indices and the number of second buffer layers 111b and 111d having low refractive indices.

For example, in case that one first buffer layer 111a or 111c and one second buffer layer 111b or 111d are provided, the thickness of the first buffer layer 111a or 111c may be 300 Å to 1,500 Å or 500 Å to 1,000 Å, and the thickness of the second buffer layer 111b or 111d may be 500 Å to 1,000 Å or 800 Å. Table 1 below shows a result of evaluating the reflectance with respect to the thicknesses of the layers in case that the multi-buffer layer 111 is disposed below the gate electrode 121 according to the implementation of the present specification, the first buffer layers 111a and 111c are made of silicon nitride (SiNx) having a refractive index of 1.98, and the second buffer layers 111b and 111d are made of silicon oxide (SiO₂) having a refractive index of 1.50.

TABLE 1

| | Thickness (Å) | | Reflectance |
|---|---|---|---|
| Classification | First buffer layer | Second buffer layer | (Aver.) |
| No. 1 | 800 | 800 | 88.8% |
| No. 2 | 500 | 800 | 88.6% |
| No. 3 | 1000 | 800 | 88.3% |
| No. 4 | 800 | 500 | 88.2% |
| No. 5 | 500 | 1000 | 88.2% |
| No. 6 | 1000 | 500 | 88.1% |
| No. 7 | 1200 | 800 | 87.9% |
| No. 8 | 800 | 1000 | 87.6% |
| No. 9 | 1200 | 500 | 87.6% |
| No. 10 | 300 | 1000 | 87.5% |
| No. 11 | 1500 | 800 | 87.3% |
| No. 12 | 1000 | 1000 | 87.3% |
| No. 13 | 300 | 800 | 87.0% |

Next, as illustrated in FIG. 3A in the present application, in case that two first buffer layers 111a and 111c and two second buffer layers 111b and 111d are provided and stacked in alternation with each other, a thickness of a first-first buffer layer 111a may be 800 Å to 1,000 Å, a thickness of a first-second buffer layer 111b may be 1,200 Å to 1,500 Å, a thickness of a second-first buffer layer 111c may be about 500 Å, and a thickness of the second-second buffer layer 111d may be about 800 Å. Table 2 below shows a result of evaluating the reflectance with respect to the thicknesses of the layers in case that the multi-buffer layer 111 includes four layers, the first buffer layers 111a and 111c are made of silicon nitride (SiNx) having a refractive index of 1.98, and the second buffer layers 111b and 111d are made of silicon oxide (SiO₂) having a refractive index of 1.50.

TABLE 2

| | Thickness (Å) | | | | |
|---|---|---|---|---|---|
| | First-first | First-second | Second-first | Second-second | Reflectance |
| Classification | buffer layer | buffer layer | buffer layer | buffer layer | (Aver.) |
| No. 1 | 800 | 1500 | 500 | 800 | 92.0% |
| No. 2 | 1000 | 1200 | 500 | 800 | 91.8% |
| No. 3 | 800 | 1200 | 500 | 800 | 91.6% |
| No. 4 | 1200 | 1000 | 500 | 800 | 91.6% |
| No. 5 | 1000 | 1500 | 500 | 800 | 91.6% |
| No. 6 | 500 | 2000 | 500 | 800 | 91.5% |
| No. 7 | 1000 | 1000 | 500 | 800 | 91.5% |
| No. 8 | 500 | 1500 | 500 | 800 | 91.5% |
| No. 9 | 800 | 1200 | 800 | 500 | 91.4% |
| No. 10 | 300 | 2000 | 500 | 800 | 91.3% |
| No. 11 | 1200 | 1200 | 500 | 800 | 91.3% |
| No. 12 | 500 | 1500 | 800 | 500 | 91.3% |
| No. 13 | 800 | 1000 | 800 | 800 | 91.2% |

With reference to Tables 1 and 2, the reflectance of the bottom surface of the liquid crystal display panel PNL may be adjusted by adjusting the numbers and thicknesses of the first buffer layers 111a and 111c and the second buffer layers 111b and 111d. In this case, with reference to the comparison between Tables 1 and 2, it can be ascertained that the reflectance becomes higher in case that the multi-buffer layer 111 includes four layers. However, in consideration of a CVD process on the multi-buffer layer 111, the multi-buffer layer 111 may include six or fewer layers instead of including an excessively large number of layers in consideration of uniformity of the buffer layers.

The multi-buffer layer 111 may be deposited by a CVD process and formed by a dry etching process. For example, the plurality of first buffer layers 111a and 111c and the plurality of second buffer layers 111b and 111d are deposited on the entire surface of the first substrate 110 by the CVD process. Thereafter, as described above, the gate electrode 121 is formed by depositing and etching aluminum alloy and copper. Thereafter, the dry etching process is performed by using the gate electrode 121, which is formed on the multi-buffer layer 111, as a mask, such that the first buffer layers 111a and 111c and the second buffer layers 111b and 111d are removed, except for the area corresponding to the gate electrode 121, such that the multi-buffer layer 111 disposed to correspond to the gate electrode 121 is formed. Therefore, the multi-buffer layer 111 is disposed to correspond to the gate electrode 121. That is, with reference to FIG. 3A, two opposite ends of the multi-buffer layer 111 may be disposed to correspond to two opposite ends of the gate electrode 121.

A gate insulation layer 131 is disposed on the gate electrode 121. The gate insulation layer 131 may be a layer for insulating the gate electrode 121 and the active layer 122, and the gate insulation layer 131 may be made of an insulating material. For example, the gate insulation layer 131 may be configured as a single layer or multilayer made of silicon oxide (SiOx) or silicon nitride (SiNx). However, the present specification is not limited thereto. The gate insulation layer 131 may cover a top surface and a side surface of the gate electrode 121 and cover a side surface of the multi-buffer layer disposed below the gate electrode 121.

The active layer 122 is disposed on the gate insulation layer 131. The active layer 122 is disposed to overlap the gate electrode 121. For example, the active layer 122 may be made of amorphous silicon, polycrystalline silicon, oxide semiconductor, or organic semiconductor. However, the present specification is not limited thereto.

The data line, the source electrode 123, and the drain electrode 124 are disposed on the active layer 122. The source electrode 123 and the drain electrode 124 are disposed on the same layer and spaced apart from each other. The source electrode 123 and the drain electrode 124 may be electrically connected to the active layer 122 while adjoining the active layer 122. The source electrode 123 extends from the data line.

A passivation layer 132 is disposed on the source electrode 123 and the drain electrode 124. The passivation layer 132 is an insulation layer for protecting the components disposed below the passivation layer 132. The passivation layer 132 may be configured as a single layer or multilayer made of silicon oxide (SiOx) or silicon nitride (SiNx). However, the present specification is not limited thereto.

A planarization layer 133 is disposed on the passivation layer 132. The planarization layer 133 is an insulation layer for planarizing an upper portion of an first substrate 110. The planarization layer 133 may be configured as a single layer or multilayer made of an organic material, for example, polyimide or photo acrylic. However, the present specification is not limited thereto. The planarization layer 133 may include a contact hole for electrically connecting the thin-film transistor 120 and a pixel electrode 142.

A common electrode 141 is formed on the planarization layer 133. The common electrode 141 is electrically connected to a common line. The common electrode 141 is configured as one large electrode and used for the subpixel SP in common. In several implementations, the common electrode 141 may include a plurality of common electrode blocks. In this case, the common electrode blocks may serve as touch electrodes of a capacitive-type touch element. The liquid crystal display device 100 may be implemented as a display device embedded with the touch element.

The common electrode 141 may be made of a transparent conductive material. For example, the transparent conductive material may be tin oxide (TO), indium tin oxide (ITO), indium zinc oxide (IZO), indium tin zinc oxide (ITZO), and the like. However, the present specification is not limited thereto.

A protective layer 134 is disposed on the common electrode 141. The protective layer 134 may be a layer for insulating the common electrode 141 and the pixel electrode 142. The protective layer 134 may be made of an inorganic insulating material or an organic insulating material. For example, the protective layer 134 may be configured as a single layer or multilayer made of silicon oxide (SiOx) or silicon nitride (SiNx). However, the present specification is not limited thereto.

The pixel electrode 142 is disposed on the protective layer 134. The pixel electrode 142 is electrically connected to the drain electrode 124 through contact holes formed through the protective layer 134, the planarization layer 133, and the passivation layer 132 disposed therebelow. FIG. 3 illustrates the pixel electrode 142 being in contact with the drain electrode 124 of the thin-film transistor 120. However, in several implementations, the pixel electrode 142 may be in contact with the source electrode of the thin-film transistor 120.

The pixel electrode 142 may have a structure having a plurality of slits. In this case, the pixel electrode 142 may be formed in a straight shape or a zigzag shape curved at least once. The liquid crystal display device 100 illustrated in FIG. 3 has a structure in which the pixel electrode 142 has a plurality of slits, and the common electrode 141 is configured as a single electrode block. However, the present specification is not limited thereto. The liquid crystal display device 100 may have a structure in which the pixel electrode 142 is configured as a single electrode block, and the common electrode 141 has a plurality of slits.

For example, the pixel electrode 142 may be made of a transparent conductive material. For example, the transparent conductive material may be tin oxide (TO), indium tin oxide (ITO), indium zinc oxide (IZO), indium tin zinc oxide (ITZO), and the like. However, the present specification is not limited thereto.

The pixel electrode 142 is spaced apart from the common electrode 141 with the protective layer 134 interposed therebetween. In case that a voltage is applied to the pixel electrode 142 through the thin-film transistor 120, a fringe field is formed between the pixel electrode 142 and the common electrode 141 spaced apart from each other. In this case, liquid crystals positioned on the pixel electrode 142 and the common electrode 141 are rotated by dielectric anisotropy, and a transmittance rate of light passing through the display area varies depending on the degree to which the liquid crystals are rotated. Therefore, the light amount of the subpixel SP may be controlled.

The second substrate 150, which is the upper substrate, is disposed opposite to the first substrate 110. The black matrix BM, the color filter 160, and a spacer 170 are disposed on the second substrate 150.

The black matrix BM is disposed on the second substrate 150 and overlaps the thin-film transistor 120, the gate line, and the data line of the first substrate 110. The black matrix BM may be made of an opaque organic material. For example, the black matrix BM may include black resin. Further, the black matrix BM may be formed in a straight shape or a zigzag shape curved at least once. The thin-film transistor 120, the gate line, and the data line may be covered by the black matrix BM. An area in which the black matrix BM is not disposed is an opening area corresponding to an area through which the light from the subpixel SP passes.

The color filter 160 is disposed on the black matrix BM. The color filter 160 includes a plurality of color filters that transmit light beams with different wavelengths. For example, the color filters may include red, green, and blue color filters including red, green, and blue pigment. The color filters may absorb or transmit light beams with particular wavelengths, thereby expressing red, green, and blue colors. The color filters may each be formed in a straight shape or a zigzag shape curved at least once. In several implementations, the position of the black matrix BM and the position of the color filter 160 may be interchangeable.

The spacer 170 is disposed between the first substrate 110 and the second substrate 150 and maintains a gap between the second substrate 150 and the first substrate 110.

The liquid crystal layer LC is disposed in the gap between the first substrate 110 and the second substrate 150 formed by the spacer 170. The liquid crystal layer LC is a layer including the liquid crystals, i.e., a layer capable of transmitting or blocking light by means of an electric field. Specifically, the liquid crystal layer LC displays images by changing light transmittance by means of an electric field generated by the common electrode 141 and the pixel electrode 142.

The liquid crystal display device according to the implementation of the present specification improves the rear reflectance of the liquid crystal display panel by means of a gate electrode, which has the structure in which aluminum alloy and copper are stacked, and a plurality of inorganic buffer layers disposed below the gate electrode and having different refractive indices. In general, copper, which is used for the gate electrode, has a disadvantage of low reflectance. In order to eliminate the disadvantage, silver, gold, and platinum, which have high reflectance, may be used, but silver, gold, and platinum are not sufficient for a subsequent etching process. In addition, in the case of the gate electrode having a MoTi-Cu dual-layer structure in the related art, the rear reflectance is low, which makes it difficult to improve the efficiency of the backlight unit BLU. Therefore, in the display device according to the implementation of the present specification, the first gate metal layer made of aluminum alloy may be disposed below the second gate metal layer made of copper, thereby improving the rear reflectance of the gate electrode. Further, the dopant material may be suitably utilized for the subsequent wet etching process by adjusting the content of the dopant material made of aluminum alloy that constitutes the first gate metal layer.

In addition, in the display device according to the implementation of the present specification, the plurality of inorganic buffer layers may be disposed below the gate electrode having the dual-layer structure including aluminum alloy and copper, thereby further improving the rear reflectance. In particular, with the particular refractive index and thickness of the inorganic buffer layer, it is possible to improve the rear reflectance of the liquid crystal display panel by 90% or more, thereby improving the efficiency of the backlight unit BLU and improving the luminance of the display device.

Hereinafter, the effect of the present specification will be described in more detail with reference to examples and comparative examples. However, the following examples are for exemplifying the present specification, and the scope of the present specification is not limited by the following examples.

### Example 1

A multi-buffer layer, in which a first-first buffer layer (SiNx, refractive index of 1.98) having a thickness of 800 Å, a first-second buffer layer (SiO2, refractive index of 1.50) having a thickness of 1,500 Å, a second-first buffer layer (SiNx, refractive index of 1.98) having a thickness of 500 Å, a second-second buffer layer (SiO2, refractive index of 1.50) having a thickness of 800 Å are sequentially stacked, was formed on a glass substrate (refractive index of 2.15). Aluminum alloy doped with neodymium (Nd, 3.3 wt %), germanium (Ge, 3.0 wt %), and tantalum (Ta, 1.5 wt %) was deposited with a thickness of 500 Å on the multi-buffer layer, and then copper with a thickness of 4,000 Å was deposited to form a dual-layer gate metal layer.

### Comparative Example 1

MoTi with a thickness of 500 Å was formed on the glass substrate, and then copper with a thickness of 4,000 Å was deposited to form a dual-layer gate metal layer.

### Comparative Example 2

Aluminum with a thickness of 500 Å was deposited on a glass substrate.

### Experimental Example 1

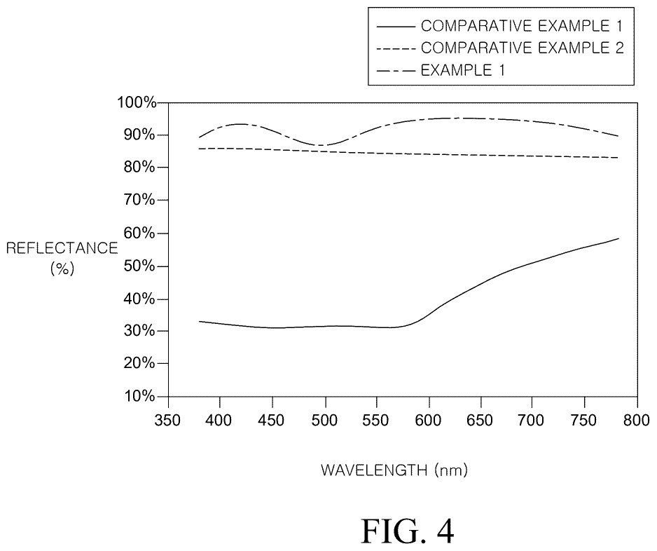

For the manufactured gate electrodes of Examples 1 and Comparative Examples 1 and 2, the reflectance was measured toward the rear surfaces of the glass sub strates by using CM2600d. The measurement results are shown in FIG. 4.

FIG. 4 is a graph illustrating rear reflectance with respect to wavelengths in Example 1 and Comparative Examples 1 and 2. With reference to FIG. 4, it was ascertained that the gate electrode having the MoTi/Cu dual-layer structure in the related art according to Comparative Example 1 had significantly low reflectance in a full wavelength band. In addition, with reference to the comparison between Example 1 and Comparative Example 2, it was ascertained that the multi-buffer layer was disposed below the aluminum alloy, the reflectance was improved in a full wavelength band, and the rear reflectance of 90% or more was achieved.

### Experimental Example 2

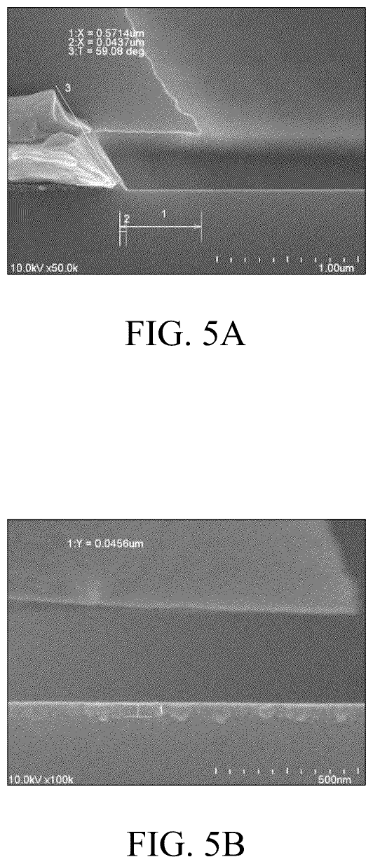

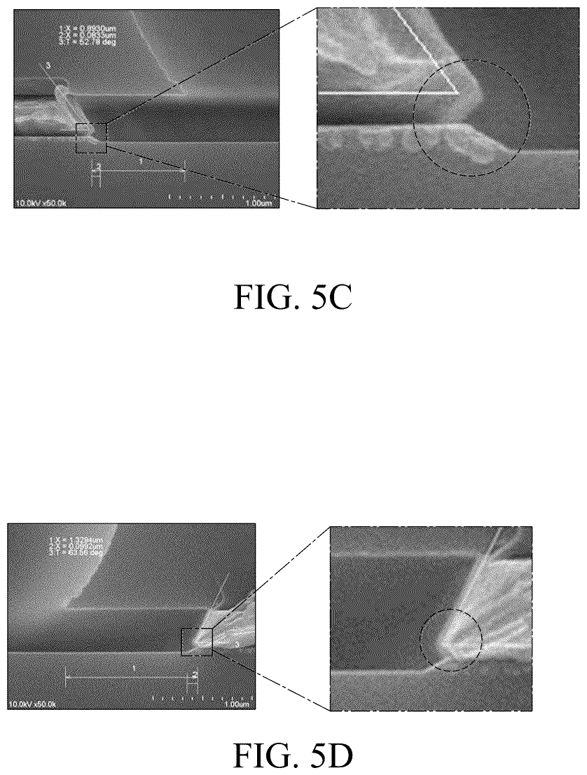

Etching characteristics of the first gate metal layer was evaluated by changing the content of the dopant material. The measurement results are shown in FIGS. 5A to 5D. FIGS. 5A to 5D are SEM images illustrating cross-sections of a dual-layer gate electrode including the first gate electrode layer made of aluminum alloy and the second gate electrode layer made of copper. FIG. 5A is an SEM image of a gate electrode in which a first gate electrode layer is made of aluminum alloy doped with 1.5 wt % zirconium (Zr). FIG. 5B is an SEM image of a gate electrode in which a first gate electrode layer is made of aluminum alloy doped with 7.0 wt % zirconium (Zr). FIG. 5C is an SEM image of a gate electrode in which a first gate electrode layer is made of aluminum alloy doped with 0.3 wt % zirconium (Zr). FIG. 5D is an SEM image of a gate electrode in which a first gate electrode layer is made of aluminum alloy doped with 0.5 wt % zirconium (Zr).

With reference to FIG. 5B, it was ascertained that the aluminum alloy was not etched in case that the content of the dopant material of aluminum alloy was more than 5 wt %. With reference to the comparison between FIGS. 5A and 5C to 5D, it was ascertained that in case that the content of the dopant material was less than 1 wt %, the etching rate for aluminum alloy increased, and an undercut occurred on the bottom surface of the aluminum alloy.

### Experimental Example 3

Hereinafter, AFM surface roughness of the first gate metal layer was measured by changing the total content of the dopant material in the entire aluminum alloy in Example 1. The surface roughness was measured by using measurement equipment XE-100 immediately after the deposition of the first gate metal layer, after the heat treatment at 400° C., and after the heat treatment at 500° C. Values of the surface roughness of the first gate metal layer based on the total content of the dopant material are shown in Table 3 below.

TABLE 3

| Total | | Ra(nm) | | Rq(nm) | | Rpv(nm) | |
|---|---|---|---|---|---|---|---|
| content of | Heat | | Two | | Two | | Two |
| dopant material | treatment | Once | times | Once | times | Once | times |
| 0.5 wt % | After | 1.4 | 1.4 | 1.8 | 1.8 | 14.2 | 14.6 |
| | deposition | | | | | | |
| | 400° C. | 1.8 | 1.8 | 2.4 | 2.3 | 24.9 | 21.8 |
| | 500° C. | 2.6 | 2.6 | 3.8 | 3.8 | 56.1 | 54.4 |
| 1.0 wt % | After | 1.3 | 1.3 | 1.6 | 1.6 | 12.7 | 12.9 |
| | deposition | | | | | | |
| | 400° C. | 1.4 | 1.4 | 1.8 | 1.7 | 19.1 | 16.6 |
| | 500° C. | 2.3 | 2.3 | 3.1 | 3.1 | 40.2 | 39.6 |
| 1.5 wt % | After | 1.1 | 1.2 | 1.4 | 1.5 | 12.4 | 13.7 |
| | deposition | | | | | | |
| | 400° C. | 1.3 | 1.3 | 1.6 | 1.7 | 17.3 | 20.6 |
| | 500° C. | 1.7 | 1.8 | 2.4 | 2.5 | 35.6 | 33.4 |
| 2.0 wt % | After | 1.0 | 0.9 | 1.2 | 1.1 | 11.4 | 10.6 |
| | deposition | | | | | | |
| | 400° C. | 1.2 | 1.4 | 1.7 | 2.2 | 31.3 | 34.4 |
| | 500° C. | 1.6 | 1.5 | 2.2 | 2.0 | 31.8 | 36.3 |

With reference to Table 3, it was ascertained that when the total content of the dopant material based on the entire aluminum alloy increased by 1.5 wt % or more, the value of the surface roughness remarkably increased. In the case of the aluminum metal, a hillock having a fine protruding portion on a surface of the aluminum metal may occur in a high-temperature environment. The hillock is transferred, in an intact manner, onto the second gate metal layer and the insulation layer positioned thereabove, which may degrade the durability and reliability of the thin-film transistor and the liquid crystal display panel. Therefore, in the liquid crystal display device according to the present specification, it is possible to improve the durability by means of the content of the dopant material of the aluminum alloy in the dual-layer gate electrode including aluminum alloy and copper.

The example implementations of the present disclosure can also be described as follows:

According to an aspect of the present disclosure, there is provided a liquid crystal display device. The liquid crystal display device comprises an upper substrate comprising a black matrix and a color filter; a lower substrate disposed opposite to the upper substrate; a multi-buffer layer disposed on the lower substrate; a thin-film transistor comprising a gate electrode, an active layer, a source electrode, and a drain electrode, the thin-film transistor being disposed on the multi-buffer layer; and a liquid crystal layer disposed on the thin-film transistor. The gate electrode includes aluminum alloy.

The gate electrode may comprise a first gate metal layer disposed on the multi-buffer layer and including the aluminum alloy, and a second gate metal layer disposed on the first gate metal layer and including copper.

The aluminum alloy may include one or more dopant materials selected from a group including neodymium (Nd), germanium (Ge), zirconium (Zr), tantalum (Ta), cerium (Ce), niobium (Nb), molybdenum (Mo), tungsten (W), rhenium (Re), titanium (Ti), vanadium (V), chromium (Cr), hafnium (Hf), ruthenium (Ru), osmium (Os), scandium (Sc), and iridium (Ir).

The total content of the dopant material based on the entire aluminum alloy may be from 1.0 wt % to 5.0 wt %.

The aluminum alloy may include one or more of neodymium, germanium, zirconium, and tantalum, and based on the entire aluminum alloy, the content of the aluminum may be from 86 wt % to 99 wt %, the content of the neodymium is from 0.1 wt % to 5 wt %, the content of the germanium is from 0.1 wt % to 3 wt %, the content of the tantalum is from 0.1 wt % to 3 wt %, and the content of the zirconium is from 0 wt % to 3 wt %.

The multi-buffer layer may comprise a first buffer layer disposed on the upper substratec and a second buffer layer disposed on the first buffer layer and having a lower refractive index than the first buffer layer.

The refractive index of the first buffer layer may be from 1.8 to 2.2, and the refractive index of the second buffer layer is from 1.3 to 1.7.

The first buffer layer may include silicon nitride (SiNx), and the second buffer layer includes silicon oxide (SiOx).

The multi-buffer layer may constitute at least four layers by disposing the first buffer layers and the second buffer layers in alternation with each other.

The multi-buffer layer may further comprise a third buffer layer disposed on the second buffer layer and made of the same material as the first buffer layer, and a fourth buffer layer disposed on the third buffer layer and made of the same material as the second buffer layer.

A thickness of the first buffer layer may be smaller than a thickness of the second buffer layer, and a thickness of the third buffer layer may be smaller than a thickness of the fourth buffer layer.

Two opposite ends of the multi-buffer layer may correspond to two opposite ends of the gate electrode.

Although the example implementations of the present disclosure have been described in detail with reference to the accompanying drawings, the present disclosure is not limited thereto and may be embodied in many different forms without departing from the technical concept of the present disclosure. Therefore, the example implementations of the present disclosure are provided for illustrative purposes only but not intended to limit the technical concept of the present disclosure. The scope of the technical concept of the present disclosure is not limited thereto. Therefore, it should be understood that the above-described example implementations are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A liquid crystal display device comprising:
an upper substrate comprising a black matrix and a color filter;
a lower substrate disposed opposite to the upper substrate;
a multi-buffer layer disposed on the lower substrate;
a thin-film transistor comprising a gate electrode, an active layer, a source electrode, and a drain electrode, the thin-film transistor being disposed on the multi-buffer layer; and
a liquid crystal layer disposed on the thin-film transistor,
wherein the gate electrode includes aluminum alloy.

2. The liquid crystal display device of claim 1, wherein the gate electrode comprises:
a first gate metal layer disposed on the multi-buffer layer, the first gate metal layer including the aluminum alloy; and
a second gate metal layer disposed on the first gate metal layer, the second gate metal layer including copper.

3. The liquid crystal display device of claim 2, wherein the aluminum alloy includes one or more dopant materials selected from a group including neodymium (Nd), germanium (Ge), zirconium (Zr), tantalum (Ta), cerium (Ce), niobium (Nb), molybdenum (Mo), tungsten (W), rhenium (Re), titanium (Ti), vanadium (V), chromium (Cr), hafnium (Hf), ruthenium (Ru), osmium (Os), scandium (Sc), and iridium (Ir).

4. The liquid crystal display device of claim 3, wherein based on the entire aluminum alloy, a total content of the dopant material is from 1.0 wt % to 5.0 wt %.

5. The liquid crystal display device of claim 4, wherein the aluminum alloy includes one or more of neodymium, germanium, zirconium, and tantalum, and
wherein based on the entire aluminum alloy, a content of the aluminum is from 86 wt % to 99 wt %, a content of the neodymium is from 0.1 wt % to 5 wt %, a content of the germanium is from 0.1 wt % to 3 wt %, a content of the tantalum is from 0.1 wt % to 3 wt %, and a content of the zirconium is from 0 wt % to 3 wt %.

6. The liquid crystal display device of claim 1, wherein the multi-buffer layer comprises:
a first buffer layer disposed on the upper substrate; and
a second buffer layer disposed on the first buffer layer, the second buffer layer having a refractive index lower than a refractive index of the first buffer layer.

7. The liquid crystal display device of claim 6, wherein the refractive index of the first buffer layer is from 1.8 to 2.2, and the refractive index of the second buffer layer is from 1.3 to 1.7.

8. The liquid crystal display device of claim 7, wherein the first buffer layer includes silicon nitride (SiNx), and the second buffer layer includes silicon oxide (SiOx).

9. The liquid crystal display device of claim 6, wherein the multi-buffer layer constitutes at least four layers by disposing the first buffer layers and the second buffer layers in alternation with each other.

10. The liquid crystal display device of claim 6, wherein the multi-buffer layer further comprises:
a third buffer layer disposed on the second buffer layer, the third buffer layer is made of the same material as the first buffer layer; and
a fourth buffer layer disposed on the third buffer layer, the fourth buffer layer is made of the same material as the second buffer layer.

11. The liquid crystal display device of claim 10, wherein a thickness of the first buffer layer is smaller than a thickness of the second buffer layer, and a thickness of the third buffer layer is smaller than a thickness of the fourth buffer layer.

12. The liquid crystal display device of claim 6, wherein two opposite ends of the multi-buffer layer correspond to two opposite ends of the gate electrode.
